(19) United States
(12) Patent Application Publication
(10) Pub. No.: US 2009/0058425 A1
(43) Pub. Date: Mar. 5, 2009

(54) METHOD AND APPARATUS TO TEST ELECTRICAL CONTINUITY AND REDUCE LOADING PARASITICS ON HIGH-SPEED SIGNALS

(75) Inventors: Gerald K. Bartley, Rochester, MN (US); Darryl J. Becker, Rochester, MN (US); Paul E. Dahlen, Rochester, MN (US); Philip R. Germann, Oronoco, MN (US); Andrew B. Maki, Rochester, MN (US); Mark O. Maxson, Mantorville, MN (US)

Correspondence Address: CANTOR COLBURN LLP - IBM ROCHESTER DIVISION, 20 Church Street, 22nd Floor, Hartford, CT, 06103, US

(73) Assignee: International Business Machines Corporation, Armonk, NY (US)

(21) Appl. No.: 11/848,652

(22) Filed: Aug. 31, 2007

(51) Int. Cl. G01R 31/02

(52) U.S. Cl. 324/537; 324/555

(57) ABSTRACT

An apparatus for testing electrical continuity of a surface mounted (SMT) electrical board includes: a printed wiring board having a first surface and an opposite second surface; a conductive signal line disposed on each of the first and second surfaces of the printed wiring board; an electrical component disposed on and electrically connected to the conductive signal line on the first surface; and a through hole extending through the printed wiring board and the conductive signal line on the second surface of the printed wiring board exposing a surface side of the conductive signal line facing the first surface of the printed wiring board. The through hole is unplated in an inside bore defining the through hole and the through hole allows direct access to the conductive signal line on the first surface to test continuity of the conductive signal line on the first surface connected to the electrical component from the second surface of the printed wiring board.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates to a method and apparatus for testing electrical continuity in a printed circuit board (PCB) assembly, and particularly to test electrical contact substantially on a top surface of a printed wiring board using probes inserted through holes from a backside of the printed wiring board.

2. Description of Background

A direct current (DC) continuity check is performed to ensure correct component attachment to the PCB during PCB assembly. The DC continuity test is typically done by contacting test probes to the plated-thru vias near components. However, this requires a connection path to be available from all topside attached components to the bottom side in-order to test the assembly entirely from the bottom side of the structure.

FIG. 1A illustrates a prior art solution to the above noted problem. To solve this problem, a conductively plated through hole 10, or a via, extends through a PCB 12 from a bottom side 14 of the PCB 12 to a topside surface trace 16, which extends to a surface mounted component 18 attached to the PCB 12. An array of probes 20 (or “bed of nails”) can then test for proper component 18 attachment via DC continuity from the backside or bottom side 14 of the PCB 12. Although the plated via 10 solves the testability issue, the plated via 10 degrades the signal quality due to the added parasitic capacitance of the plated via 10. FIG. 1B schematically depicts the added parasitic capacitance. The capacitive stub of the plated via 10 poses a significant problem of signal degradation on high speed network devices.

Alternatively, testing of the component via a backside probe is avoided altogether, and thus a plated via is not necessary. Although this approach solves the signal degradation problem, it introduces a potential yield/shipped product quality level (SPQL) problem since the component and the related circuit connections are not tested.

Other solutions to the above described problem include using roving/flying-head probes or post-reflow optical inspection. These techniques can test for proper component attachment to the PCB without requiring a plated via corresponding to the surface mounted components. However, these technique has a much slower throughput and increases the cost of testing when compared to “bed of nails” testing. Therefore, use of roving/flying-head probes or post-reflow optical inspection are not desired to test component attachment for high-volume suppliers.

Yet another solution to the plated via include back drilling the plated vias after testing to eliminate the capacitive stub effects. However, this approach too proves to be more costly, slower and adds additional processing steps when compared to “bed of nails” testing.

Still another solution includes changing the PCB layout. For example, the signals could be routed on the bottom side of the PCB, then routed to the topside of the PCB where the component is attached and then routed back down to the bottom side of the PCB. However, this approach too degrades signal integrity and is not always permitted in the particular board layout/route.

Therefore, a need still exists to enhance the “bed of nails” approach to PCB assembly testing that maintains test coverage and does not degrade signal quality.

### SUMMARY OF THE INVENTION

The shortcomings of the prior art are overcome and additional advantages are provided through the provision of an apparatus for testing electrical continuity of a surface mounted (SMT) electrical board. The apparatus includes: a printed wiring board having a first surface and an opposite second surface; a conductive signal line disposed on each of the first and second surfaces of the printed wiring board; an electrical component disposed on and electrically connected to the conductive signal line on the first surface; and a through hole extending through the printed wiring board and the conductive signal line on the second surface of the printed wiring board exposing a surface side of the conductive signal line facing the first surface of the printed wiring board. The through hole is unplated in an inside bore defining the through hole and the through hole allows direct access to the conductive signal line on the first surface to test continuity of the conductive signal line on the first surface connected to the electrical component from the second surface of the printed wiring board.

In another embodiment, a method for testing electrical continuity of a surface mounted (SMT) electrical board is provided. The method includes: disposing a conductive signal line on a first surface and an opposite second surface of a printed wiring board; extending a through hole through the printed wiring board and the conductive signal line on the second surface of the printed wiring board thereby exposing a surface side facing the first surface of the printed wiring board; masking the through hole to prevent plating of the through hole; plating the first and second surfaces of the printed wiring board; and surface mounting an electrical component to the first surface of the printed wiring board to electrically connect the electrical component to the conductive signal line on the first surface. The through hole is unplated in an inside bore defining the through hole and the through hole allows direct access to the conductive signal line on the first surface to test continuity of the conductive signal line on the first surface connected to the electrical component from the second surface of the printed wiring board.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1A is a perspective view of a PCB assembly illustrating a conventional array of probes for testing component attachment in accordance with the prior art;

FIG. 1B is an enlarged partial cross-sectional view of FIG. 1A illustrating a conventional plated through hole in accordance with the prior art;

FIG. 2A is a perspective view of an exemplary embodiment of a PCB assembly having a pair of non-plated through holes and an array of probes having microprobes for testing component attachment via the unplated holes in accordance with the present invention;

FIG. 2B is an enlarged partial cross-sectional view of FIG. 2A illustrating the exemplary non-plated through hole receiving one of the micro probes from a backside of the PCB assembly in accordance with the present invention; and

FIGS. 3A-3D are cross-sectional views illustrating an exemplary embodiment of a method of forming the non-plated through holes in a PCB assembly for testing component attachment with microprobes from the bottom side of the PCB assembly in accordance with the present invention.

The detailed description explains the preferred embodiments of the invention, together with advantages and features, by way of example with reference to the drawings.

### DETAILED DESCRIPTION OF THE INVENTION

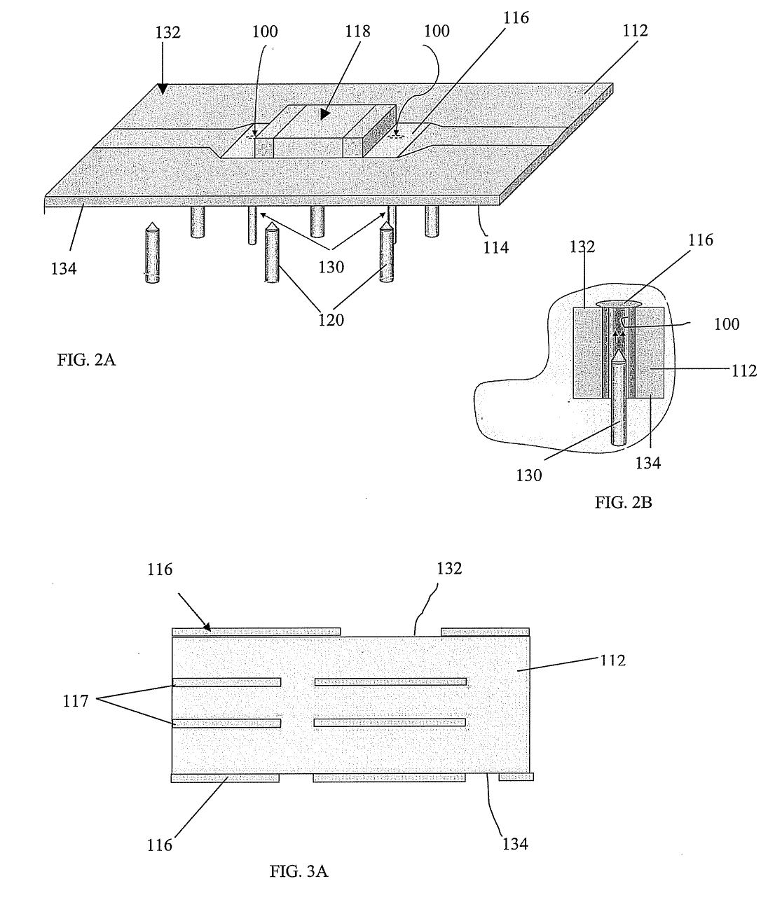

Turning now to the drawings in greater detail, it will be seen that FIG. 2A is a perspective view of an exemplary embodiment of a PCB assembly having a pair of non-plated through holes and an array of probes having microprobes for testing component attachment via the unplated holes in accordance with the present invention. More specifically, FIG. 2A illustrates a solution to the above noted problems. A non-conductive and non-plated through hole 100, or a via, extends through a printed wiring board (PWB) or printed circuit board (PCB) 112 from a bottom side 114 of the PCB 112 to a topside surface trace 116, which extends to a surface mounted (SMT) component 118 attached to the PCB 112. An array of probes 120 (or “bed of nails”) can then test for DC continuity on a surface trace (not shown) on the backside or bottom side 114 of the PCB 112, as best seen in FIG. 2A, while small microprobes 130 can test for proper component 118 attachment via DC continuity from the backside or bottom side 114 of the PCB 112, as best seen in FIG. 2B.

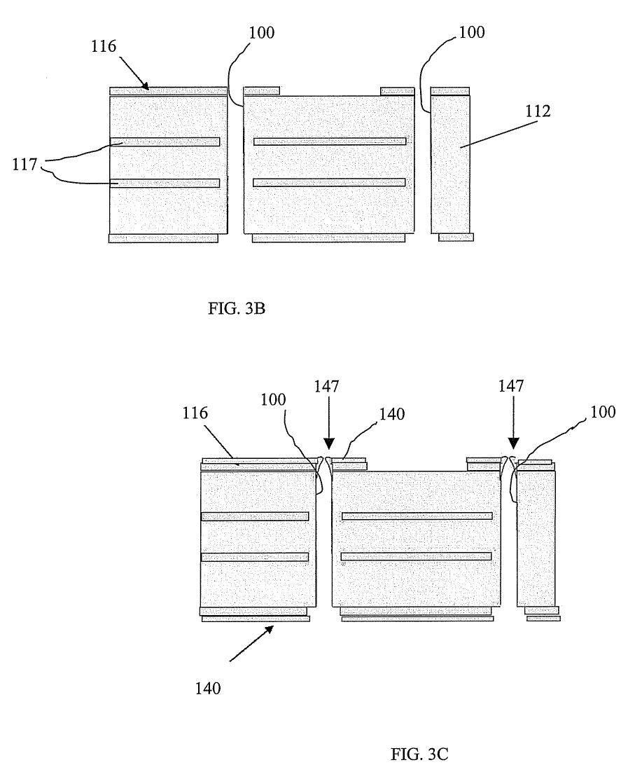

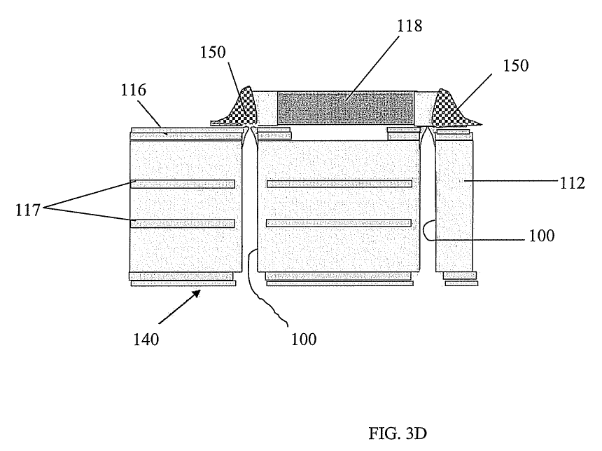

Referring to FIGS. 2A and 2B, the printed wiring board 112 has a first surface 132 and an opposite second surface 134. The topside surface trace 116 is a conductive signal line disposed on each of the first and second surfaces 132, 134 of the printed wiring board 112. In exemplary embodiments, the conductive signal line 116 is a base copper tracing (see FIG. 3A). The surface mounted device or electrical component 118 is disposed on the first surface 132 and is electrically connected to the conductive signal line 116 on the first surface. The non-conductive and non-plated through hole or via 100 extends through the printed wiring board 112 and the conductive signal line 116 on the second surface 134 of the printed wiring board 116, thereby exposing both sides of the conductive signal line 116 on the first surface 132 connected to the electrical component 118, as best seen with reference to FIG. 2B.

The through hole 100 is unplated in an inside bore defining the through hole 100 and the bore has a diameter small enough to allow access to test continuity of the conductive signal line 116 connected to the electrical component 118 from the second surface 134 of the printed wiring board 112. A miniature probe or microprobe 130 as shown in FIGS. 2A and 2B is utilized for insertion from the bottom side of the PCB 112 through the unplated hole 100 to make contact with the desired topside component/net trace 118/116. In exemplary embodiments the probe 130 is smaller than the diameter of the through hole 100, but is not limited thereto. For example, the probe 130 may be about 0.005 inches in diameter, while the diameter of the through hole 100 is between about 0.006 inches and 0.007 inches, but is not limited thereto

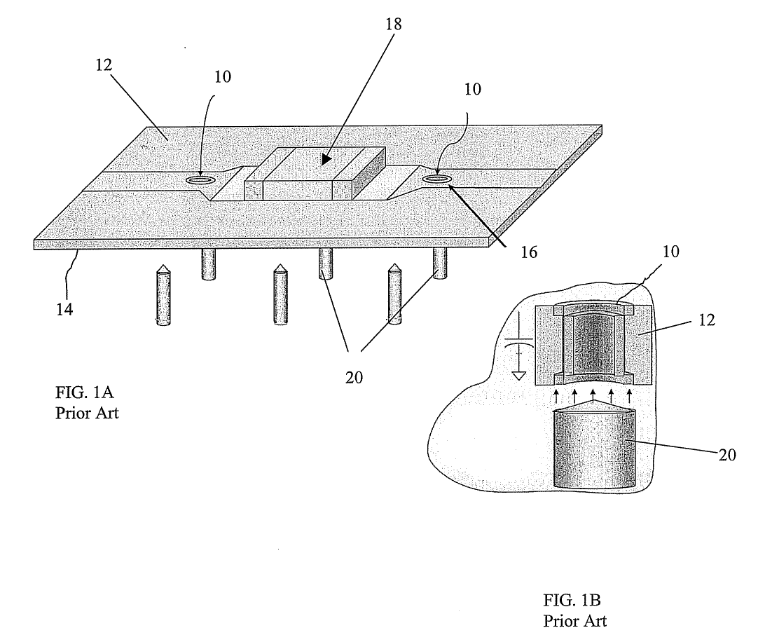

The small diameter through hole 100 in combination with the smaller probe 130 enables testing of components 118 underneath or shadowed by other components where the frequency of operation for that signal would be adversely affected by the typical via stub illustrated in FIGS. 1A and 1B. Alternatively, the use of the typical via stub illustrated in FIGS. 1A and 1B would block wiring that otherwise could have escaped on the surfaces of the next level of circuitry.

In an alternative exemplary embodiment and referring to FIGS. 3A-3D, a method for testing electrical continuity of a surface mounted (SMT) electrical board is provided. The method includes disposing a conductive signal line 116 on a first surface 132 and an opposite second surface 134 of a printed wiring board 112. In exemplary embodiments, the conductive signal line is base copper. FIG. 3A illustrates the printed wiring board 112 as raw card not only with conductive signal lines 116 on the first and second surfaces, internal conductive signal lines 117 formed by basic internal etching as known in the art.

Referring now to FIG. 3B, a through hole 100 is formed to extend through the printed wiring board 112 and the conductive signal line 116 on the second surface 134 of the printed wiring board 112. The through hole 100 may be formed by one of drilling, punching, etching or using a laser. The through hole 100 exposes both sides of the conductive signal line 116 aligned with the through hole, which is disposed on the first surface 132 of the printed wiring board 112. In an exemplary embodiment, the diameter of the through hole 100 is configured to receive a microprobe 130 (see FIG. 2B) from the second surface 134 of the printed wiring board 112 to test electrical continuity of the conductive signal line 116 connected to the electrical component 118 from the second surface 134 of the printed wiring board 112. For example, the through hole is formed having a diameter between about 0.006 inches to about 0.007 inches, but is not limited thereto.

In an alternative exemplary embodiment, it will be recognized that an end portion of one of the probes 120 as illustrated in the array of probes of FIG. 1A may have a reduced diameter to function as a microprobe 130. In other words, the probe is standard size except for a very short portion that is tapered, for example.

Referring now to FIG. 3C, the through hole 100 is masked to prevent plating of the through hole 100 and the first and second surfaces 132 and 134 of the printed wiring board 112 are plated indicated generally with plating 140 disposed on the conductive signal lines 116. Next, the electrical component 118 is surface mounted at terminal portions 147 (see FIG. 3D) of the conductive signal line 116 on the first surface 132 of the printed wiring board 112 to electrically connect the electrical component 118 to the conductive signal line 116 on the first surface 132.

Surface mounting the electrical component 118 at terminal portions 147 of the conductive signal line 116 on the first surface 132 of the printed wiring board 112 includes solder screen pasting generally indicated with solder 150, placing the electrical component 118 for electrical connection at the terminal portions 147 and reflowing the solder 150.

The through hole 100 is configured having a small enough diameter during raw card processing such that the walls defining the diameter of the through hole 100 are not plated during plating, solder paste screening and reflow, thus preventing seepage of conductive material into the through hole 100. By limiting seepage of the conductive material into the through hole 100, the formation of parasitic capacitance or a capacitive stub is eliminated or effectively reduced.

The through hole 100 is left unplated in an inside bore defining the through hole, allowing access to test electrical continuity of the conductive signal line 116 through the electrical component 118 connected thereto, thereby testing for proper component attachment to the board 112. Proper component attachment can be tested from the second surface 134 of the printed wiring board 112.

Another embodiment of the process to create the unplated hole 100 is to use an excimer laser (not shown) after plating the first and second surfaces 132 and 134 of the board 112. The excimer laser removes dielectric material but will not remove copper. In this alternative embodiment, the process is similar to the method described above, but ensures that no copper covered bottom side access to the topside trace (e.g., a copper ‘antipad’ is inserted into the CAD of the board design during layout). Once the plating is completed, the excimer laser is utilized to create the unplated hole 100 allowing for bottom side access to the topside trace to test for proper component attachment.

In either method, a small hole is created where contact to a topside trace is desired. During raw card processing, the walls defining this through hole 100 are not plated. The unplated holes 100 do not have parasitic capacitance normally associated with vias. The hole 100 is small enough such that during plating, solder paste screening, and reflow, the seepage of conductive material into the hole is minimal. During “bed of nails” testing, which tests for proper component connection, a small probe is inserted through the hole 100 and contacts the bottom of the metal pad/trace on the topside surface, thus allowing contact from the bottom side of the board to the topside component/trace.

It will be recognized by those skilled in the pertinent art that although the exemplary embodiments described above pertain to solder connection, the present invention is not limited thereto. For example, the present invention may be used with land grid array (LGA), temporary chip attachment (TCA), or other attach approach in addition to a soldered connection.

In the above described embodiments, the additional small probing hole does not plate significantly far down into the PCB, if at all. The small probing hole is dimensioned such that it is not plated during the plating process, and is small enough such that solder will not wick down the hole. In addition, a solder mask tent and/or dam may be used to prevent solder from entering the hole in the first place. Moreover, as discussed above, the above described probing technique is not necessarily limited to applications where solder attach is used. Although the prior art often uses simply DC test stimulus, as we discuss in the present the invention, it will be recognized by those skilled in the art the alternating current (AC) testing, including time domain reflectometry (TDR), vector network analyzers (VNA), and other ratio type measurements may be facilitated

While the preferred embodiments to the invention have been described, it will be understood that those skilled in the art, both now and in the future, may make various improvements and enhancements which fall within the scope of the claims which follow. These claims should be construed to maintain the proper protection for the invention first described.

What is claimed is:

1. An apparatus for testing electrical continuity of a surface mounted (SMT) electrical board comprising:
a printed wiring board having a first surface and an opposite second surface;
a conductive signal line disposed on each of the first and second surfaces of the printed wiring board;
an electrical component disposed on and electrically connected to the conductive signal line on the first surface; and
a through hole extending through the printed wiring board and the conductive signal line on the second surface of the printed wiring board exposing a surface side of the conductive signal line facing the first surface of the printed wiring board,
wherein the through hole is unplated in an inside bore defining the through hole and the through hole allows direct access to the conductive signal line on the first surface to test continuity of the conductive signal line on the first surface connected to the electrical component from the second surface of the printed wiring board.

2. The surface mounted (SMT) electrical board of claim 1, wherein the conductive signal line is a base copper tracing.

3. The surface mounted (SMT) electrical board of claim 2, wherein the diameter of the through hole has a diameter less than about 0.007 inches.

4. The surface mounted (SMT) electrical board of claim 2, wherein the diameter of the through hole is between about 0.006 inches to about 0.007 inches.

5. The surface mounted (SMT) electrical board of claim 2, wherein the diameter of the through hole is configured to receive a probe having a diameter less than a diameter of the inside bore defining the through hole from the second surface of the printed wiring board to test continuity of the conductive signal line connected to the electrical component from the second surface of the printed wiring board.

6. The surface mounted (SMT) electrical board of claim 2, wherein the through hole is aligned with conductive signal line on the first surface corresponding to at least one of a metal pad of the electrical component and an end portion of a trace.

7. A method for testing electrical continuity of a surface mounted (SMT) electrical board comprising:
disposing a conductive signal line on a first surface and an opposite second surface of a printed wiring board;
extending a through hole through the printed wiring board and the conductive signal line on the second surface of the printed wiring board thereby exposing a surface side facing the first surface of the printed wiring board;
masking the through hole to prevent plating of the through hole;
plating the first and second surfaces of the printed wiring board; and
surface mounting an electrical component to the first surface of the printed wiring board to electrically connect the electrical component to the conductive signal line on the first surface,
wherein the through hole is unplated in an inside bore defining the through hole and the through hole allows direct access to the conductive signal line on the first surface to test continuity of the conductive signal line on the first surface connected to the electrical component from the second surface of the printed wiring board.

8. The method of claim 7, wherein the conductive signal line is a base copper tracing.

9. The method of claim 7, wherein the diameter of the through hole has a diameter less than about 0.007 inches.

10. The method of claim 7, wherein the diameter of the through hole is between about 0.006 inches to about 0.007 inches.

11. The method of claim 7, further comprising:
receiving a probe having a diameter less than a diameter of the inside bore defining the through hole from the second surface of the printed wiring board to test continuity of the conductive signal line connected to the electrical component from the second surface of the printed wiring board.

12. The method of claim 11, wherein the probe has a diameter of about 0.005 inches.

13. The method of claim 7, wherein the extending the through hole through the printed wiring board and the conductive signal line on the second surface of the printed wiring board includes one of drilling, punching, etching or using a laser to form the through hole.

14. The method of claim 13, wherein the extending the through hole through the printed wiring board and the conductive signal line on the second surface of the printed wiring board is completed using an excimer laser after the plating the first and second surfaces.

15. The method of claim 7, wherein the surface mounting the electrical component to the first surface of the printed wiring board includes solder screen pasting, placing the electrical component on the first surface of the printed wiring board and reflowing.
